(19) United States
(12) Patent Application Publication
(10) Pub. No.: US 2013/0256738 A1
(43) Pub. Date: Oct. 3, 2013

(54) LIGHT EMITTING DIODE COMPONENT, LIGHT EMITTING DIODE PACKAGE AND MANUFACTURING METHOD THEREOF

(71) Applicants: LEXTAR ELECTRONICS (SUZHOU) CORPORATION, Jiang Su (CN); LEXTAR ELECTRONICS CORPORATION, Hsinchu (TW)

(72) Inventors: Jiao LI, Jiang Su (CN); Chun-E LI, Jiang Su (CN)

(73) Assignees: LEXTAR ELECTRONICS CORPORATION, Hsinchu (TW); LEXTAR ELECTRONICS (SUZHOU) CORPORATION, Jiang Su (CN)

(21) Appl. No.: 13/831,514

(22) Filed: Mar. 14, 2013

(30) Foreign Application Priority Data
Mar. 30, 2012 (CN) 201210089247.6

(51) Int. Cl. H01L 33/62

(52) U.S. Cl. CPC H01L 33/62
USPC 257/99; 438/22

(57) ABSTRACT

A light emitting diode component, a light emitting diode package and the manufacturing method thereof are provided. The LED component includes a semiconductor epitaxial stack structure, a first electrode and a second electrode. The semiconductor epitaxial stack structure has a bottom surface, a top surface, a first lateral surface, and a second lateral surface. The first electrode is disposed on the first lateral surface. The second electrode is disposed on the bottom surface.

### RELATED APPLICATIONS

This application claims priority to China Application Serial Number 201210089247.6, filed Mar. 30, 2012, which is herein incorporated by reference.

### BACKGROUND

1. Technical Field

Embodiments of the present invention relate to a light emitting diode. More particularly, embodiments of the present invention relates to a light emitting diode component, a light emitting diode package and the manufacturing method thereof.

2. Description of Related Art

A general light emitting diode (LED) includes an epitaxial stack structure disposed on a substrate. The expitaxial stack structure includes an N-type semiconductor layer, a MQW (Multiple Quantum Wells) and a P-type semiconductor layer stacking one by one. When the N-type semiconductor layer and the P-type semiconductor layer are respectively driven by the applied voltage, electrons and electronic holes can be combined in the MQW to emit light.

An N electrode and a P electrode are generally formed on the N-type semiconductor layer and the P-type semiconductor layer, respectively. In order to bond wires between the electrodes and the lead frame, these electrodes are both exposed on the same side of the LED. The P electrode is disposed on the surface of the P-type semiconductor layer. However, in that the N-type semiconductor layer is covered by the MOW and the P-type semiconductor layer, parts of the MOW and the P-type semiconductor layer must be removed to dispose the N electrode thereover.

Since parts of the MOW and the P-type semiconductor layer are removed, the illumination area would consequently reduced, and thus the decreased illumination efficiency. Further, because the electrodes of LED are electrically connected to the lead frames by wires, the risk of broken wires exists.

### SUMMARY

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In accordance with one embodiment of the present invention, a light emitting diode component includes a semiconductor epitaxial stack structure, a first electrode and a second electrode. The semiconductor epitaxial stack structure has a bottom surface, a top surface opposite to the bottom surface, a first lateral surface, and a second lateral surface opposite to the first lateral surface. The first electrode is disposed on the first lateral surface of the semiconductor epitaxial stack structure. The second electrode is disposed on the bottom surface of the semiconductor epitaxial stack structure.

In accordance with another embodiment of the present invention, a light emitting diode package includes a light emitting diode component, a first lead frame, a second lead frame and a package. The light emitting diode component includes a semiconductor epitaxial stack structure, a first electrode and a second electrode. The semiconductor epitaxial stack structure includes a bottom surface opposite to the top surface, a top surface, a first lateral surface, and a second lateral surface opposite to the second lateral surface. The first electrode is disposed on the first lateral surface of the semiconductor epitaxial stack structure. The second electrode is disposed on the bottom surface of the semiconductor epitaxial stack structure. The first lead frame is electrically connected to the first electrode of the light emitting diode component. The second lead frame is electrically connected to the second electrode of the light emitting diode component. The package contains the light emitting diode component, the first lead frame and the second lead frame.

In accordance with yet another embodiment of the present invention, a method for manufacturing a light emitting diode component includes the following steps: providing a substrate; forming a semiconductor epitaxial stack structure on the substrate, in which the semiconductor epitaxial stack structure sequentially includes a second semiconductor layer disposed on the substrate, an illumination layer and a first semiconductor layer: etching the first semiconductor layer, the illumination layer and the second semiconductor layer to form at least two grooves for insulation layers on the substrate; depositing at least one insulation material in the grooves for insulation layers to form at least one first insulation layer and a second insulation layer; etching the first insulation layer to form a first electrode groove on a lateral surface of the first semiconductor layer; depositing at least one first conductive material in the first electrode groove to form at least one first electrode; and forming at least one second electrode on the bottom surface of the second semiconductor layer.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following to detailed description of the embodiment, with reference made to the accompanying drawings as follows:

FIG. 1 is a cross-sectional view of a light emitting diode (LED) component in accordance with one embodiment of the present invention;

FIG. 2 is a cross-sectional view of the LED component in accordance with another embodiment of the present invention;

FIG. 3A is a cross-sectional view of the LED component in accordance with yet another embodiment of the present invention;

FIG. 36 is a cross-sectional view of the LED component in accordance with yet another embodiment of the present invention;

FIG. 4A is a cross-sectional view of a LED package in accordance with one embodiment of the present invention;

FIG. 48 is a partial side view of the LED package shown in FIG. 4A;

FIG. 4C is a partial side view of the first lead frame shown in FIG. 4A;

FIGS. 5A-5I are cross-sectional views of the LED components during the manufacturing process in accordance with one embodiment of the present invention;

FIGS. 6A to 6C are cross-sectional views of the LED components during the manufacturing process in accordance with another embodiment of the present invention.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

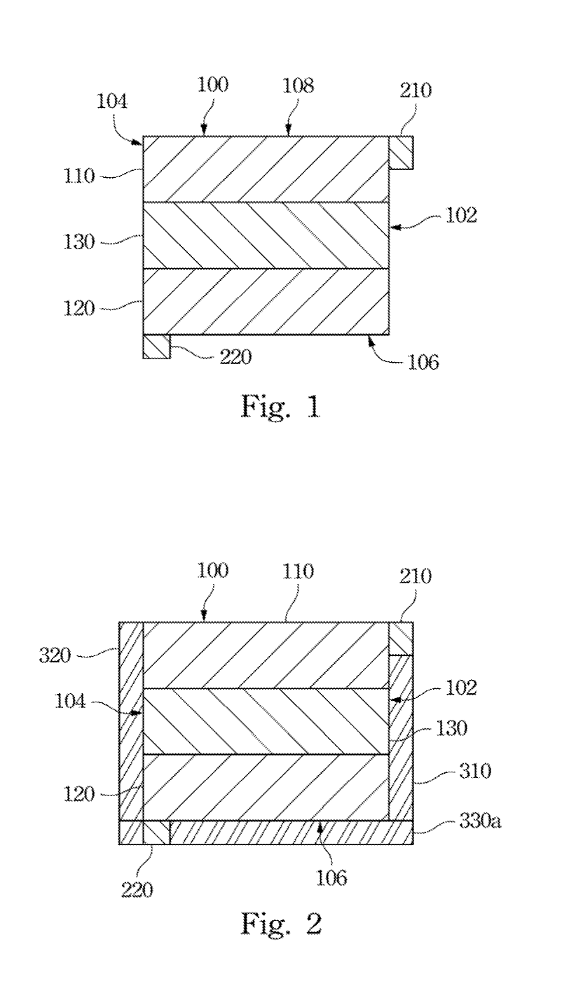

FIG. 1 is a cross-sectional view of a light emitting diode (LED) component in accordance with one embodiment of the present invention. As shown in this figure, the LED component includes a semiconductor epitaxial stack structure 100, a first electrode 210 and a second electrode 220. The semiconductor epitaxial stack structure 100 has a bottom surface 106, a top surface 108, a first lateral surface 102, and a second lateral surface 104. The bottom surface 106 is opposite to the top surface 108, and the first lateral surface 102 is opposite to the second lateral surface 104. The first electrode 210 is disposed on the first lateral surface 102 of the semiconductor epitaxial stack structure 100. The second electrode 220 is disposed on the bottom surface 100 of the semiconductor epitaxial stack structure 100.

In this embodiment, because the first electrode 210 is disposed on the first lateral surface 102, it does not block the light passing through the top surface 108 of the semiconductor epitaxial stack structure 100. Further, because the second electrode 220 is disposed under the bottom surface 106 of the semiconductor epitaxial stack structure 100, there is no need to etch the semiconductor epitaxial stack structure 100 to expose the second electrode 220, so that the illumination area is not reduced.

In some embodiments, the first lateral surface 102 and the bottom surface 106 are substantially perpendicular. It is noted that the term “substantially” in the whole specification refers to the fact that embodiments having any tiny variation or modification not affecting the essence of the technical features can be included in the scope of the present invention. For example, the angle included between the first lateral surface 102 and the bottom surface 106 can not only be 90 degrees, but also it can be slightly more or less than 90 degrees due to manufactured by different process, such as, for example, the first lateral surface 102 can be slightly tilted or curved due to isotropic etching.

FIG. 2 is a cross-sectional view of the LED component in accordance with another embodiment of the present invention. The embodiment is similar to which of FIG. 1, and the main difference is that the LED component of the embodiment further includes a first insulation layer 310, a second insulation layer 320 and a passivation layer 330a. In this embodiment, the first lateral surface 102 includes an area that is not occupied by the first electrode 210, and the first insulation layer 310 covers this area of the first lateral surface 102. Specifically, the first insulation layer 310 is adjacent to the first electrode 210, and the first lateral surface 102 of the semiconductor epitaxial stack structure 100 is entirely covered by the first electrode 210 and the first insulation layer 310.

In this embodiment, the second insulation layer 320 covers the second lateral surface 104 of the semiconductor epitaxial stack structure 100. Specifically, the second lateral surface 104 of the semiconductor epitaxial stack structure 100 is entirely covered by the second insulation layer 320. Therefore, the first insulation layer 310 and the second insulation layer 320 can protect the semiconductor epitaxial stack structure 100 from the ambient electric field, such as static electricity. In this embodiment, the first insulation layer 310 and the second insulation layer 320 are formed by insulation materials, such as SiO₂.

In this embodiment, the bottom surface 106 includes an area that is not occupied by the second electrode 220. The passivation layer 330a covers this area of the bottom surface 106, and further covers the opposite lateral walls of the second electrode 220, and is adjacent to the first insulation layer 310 and the second insulation layer 320. Specifically, the bottom surface 106 of the semiconductor epitaxial stack structure 100 is entirely covered by the second electrode 220 and the passivation layer 330a, and two ends of the passivation layer 330a are respectively adjacent to the first insulation layer 310 and the second insulation layer 320. In this embodiment, the passivation layer 330a is an insulation layer, and it can be formed by insulation materials, such as SiO₂.

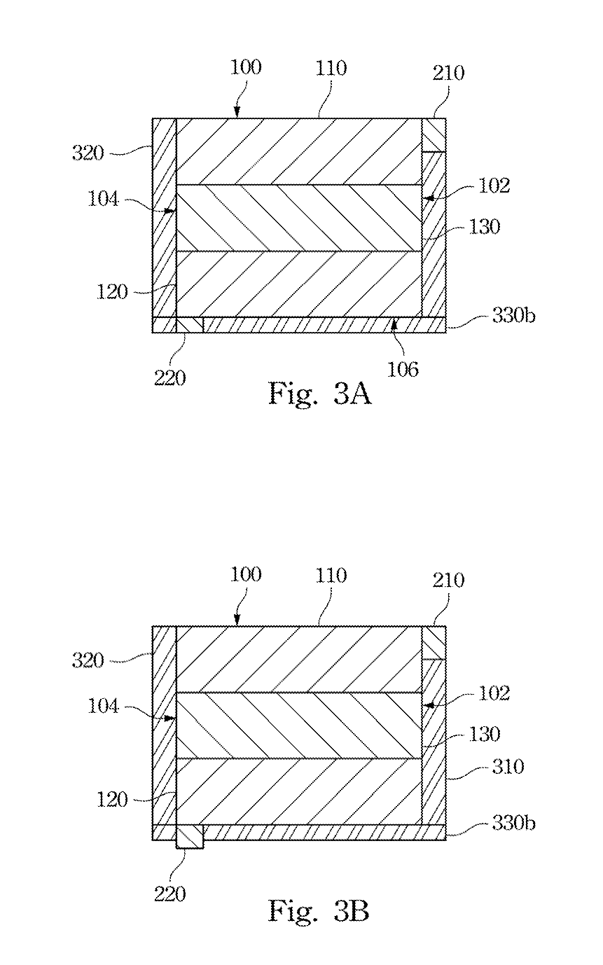

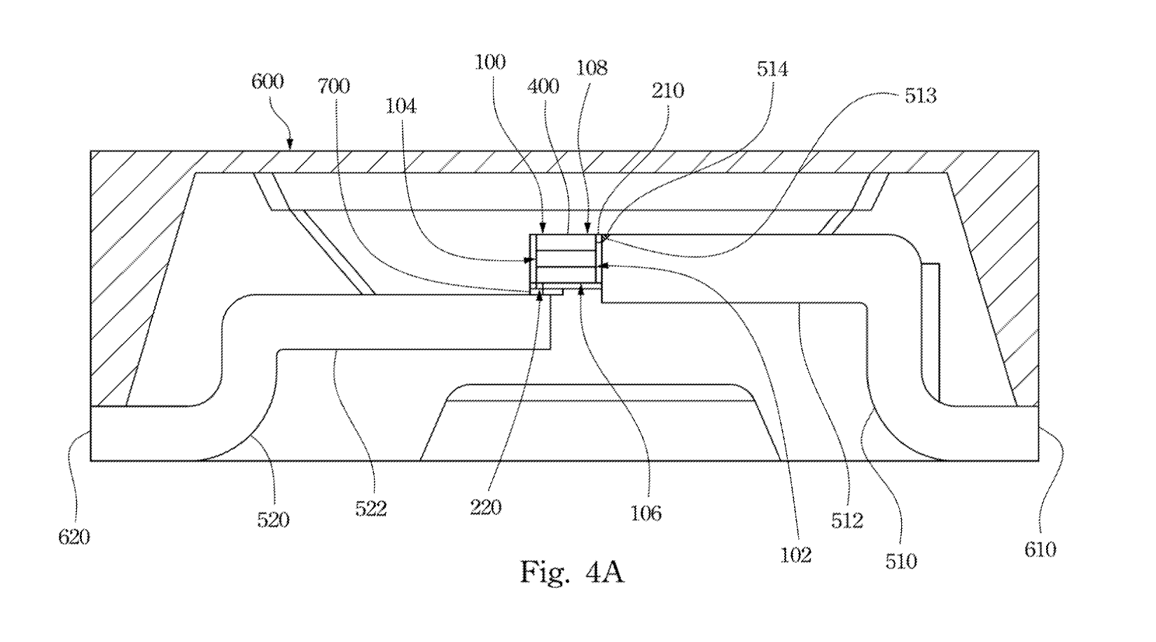

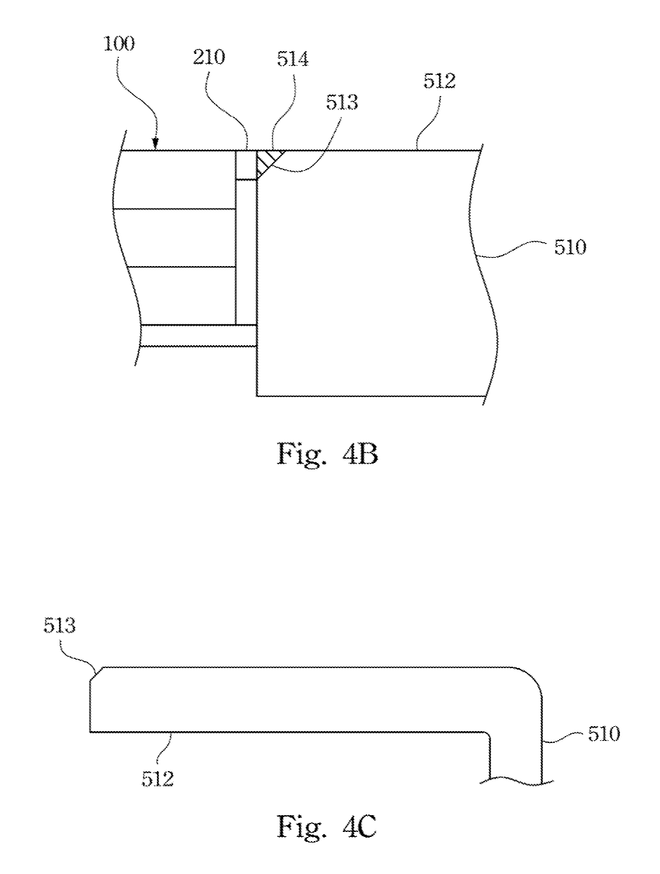

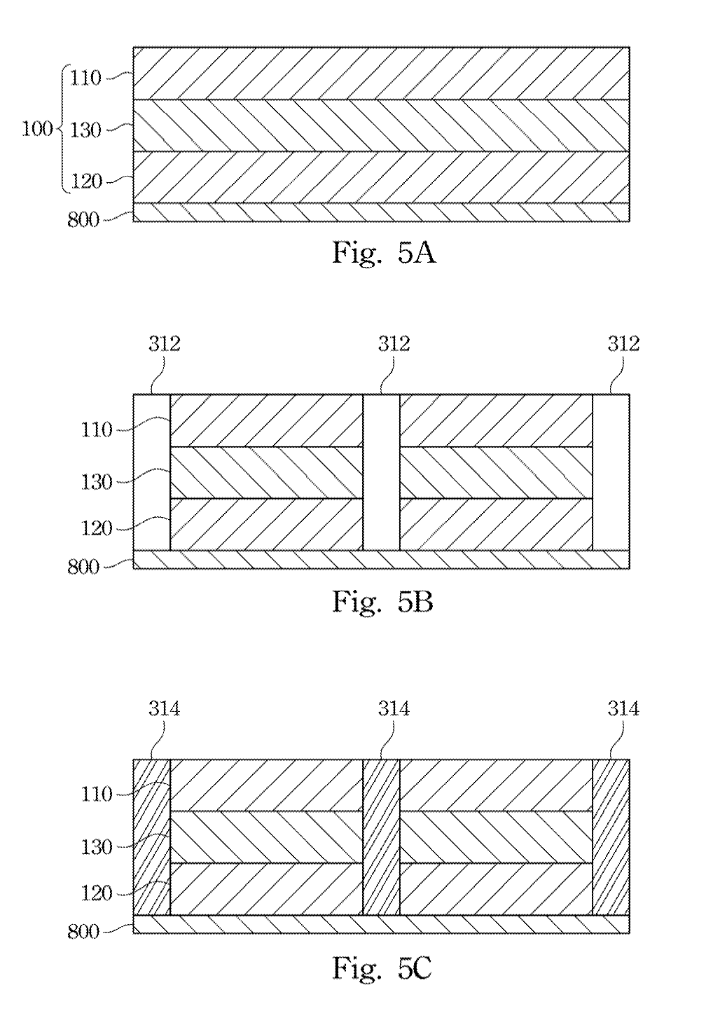

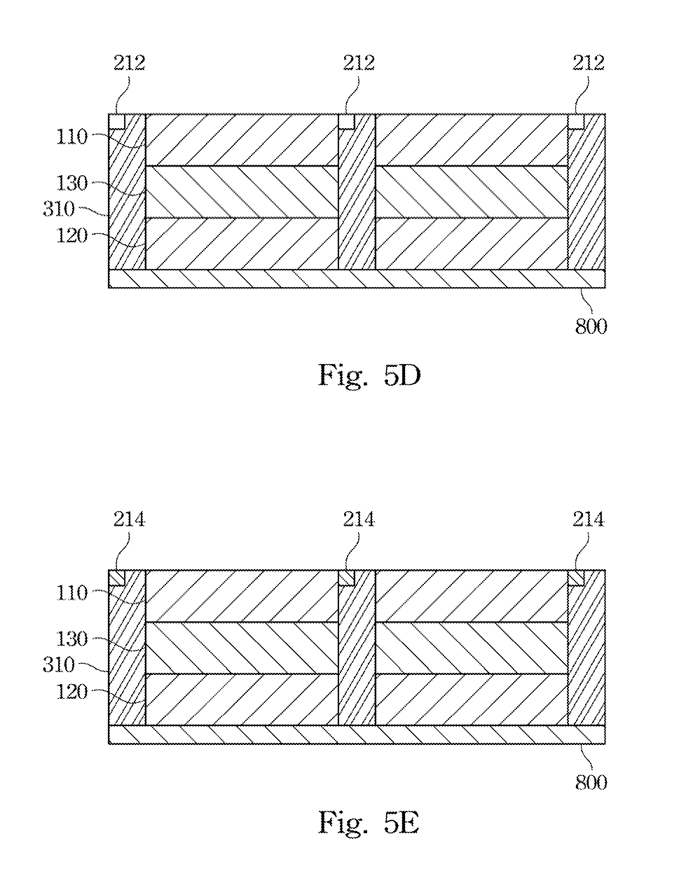

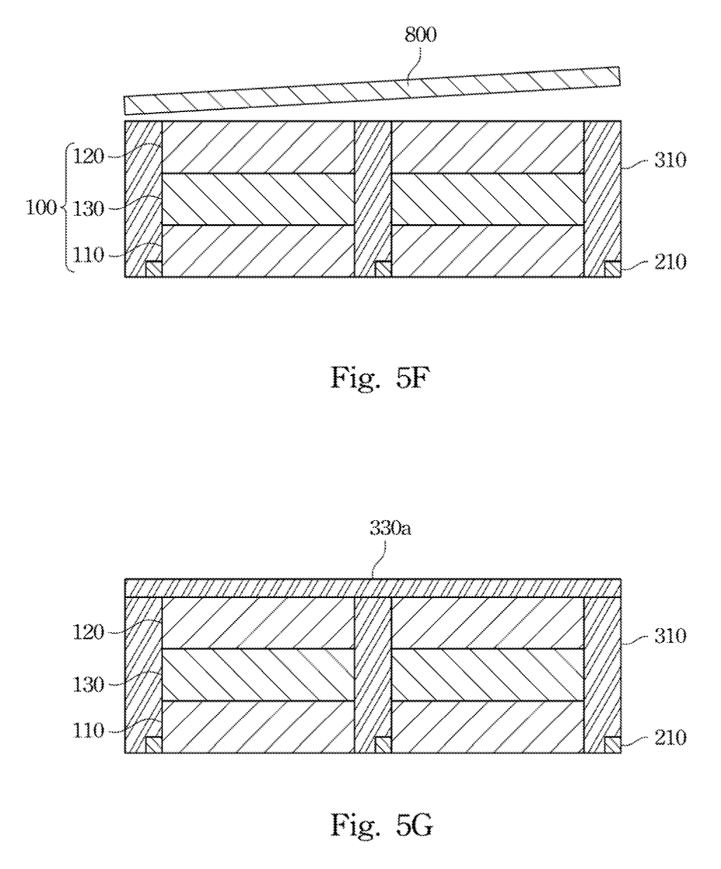

FIG. 3A is a cross-sectional view of the LED component in accordance with yet another embodiment of the present invention. This embodiment is similar to which of FIG. 2, and the main difference is that the passivation layer 330b is a semiconductor substrate, and the passivation layer 330a shown in FIG. 2 is an insulation layer. The semiconductor substrate may include, but is not limited to include, a sapphire substrate or a silicon substrate. In this embodiment, the thickness of the second electrode 220 and the thickness of the passivation layer 330b are substantially equal.

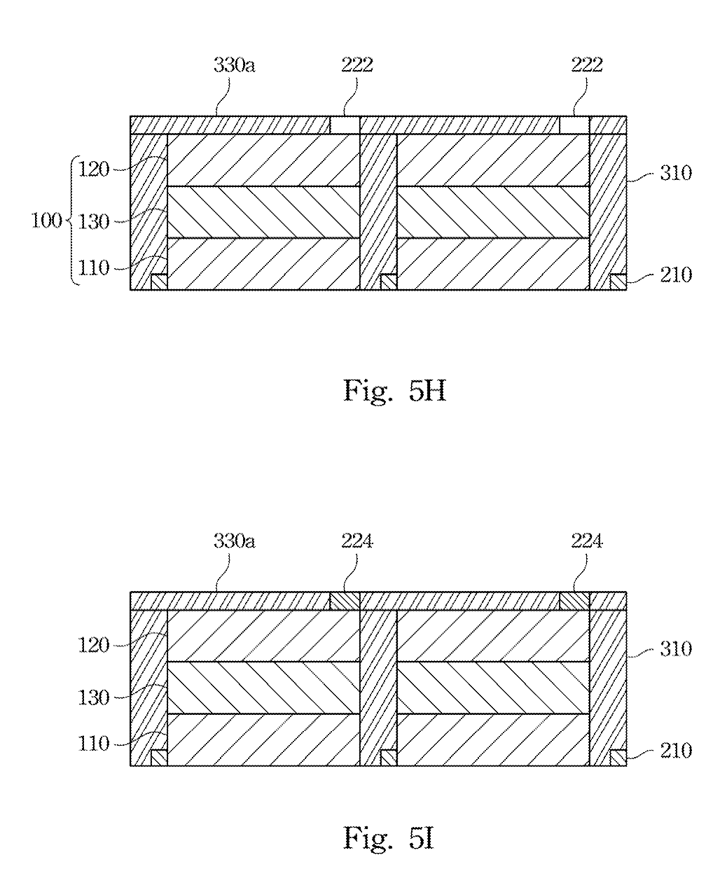

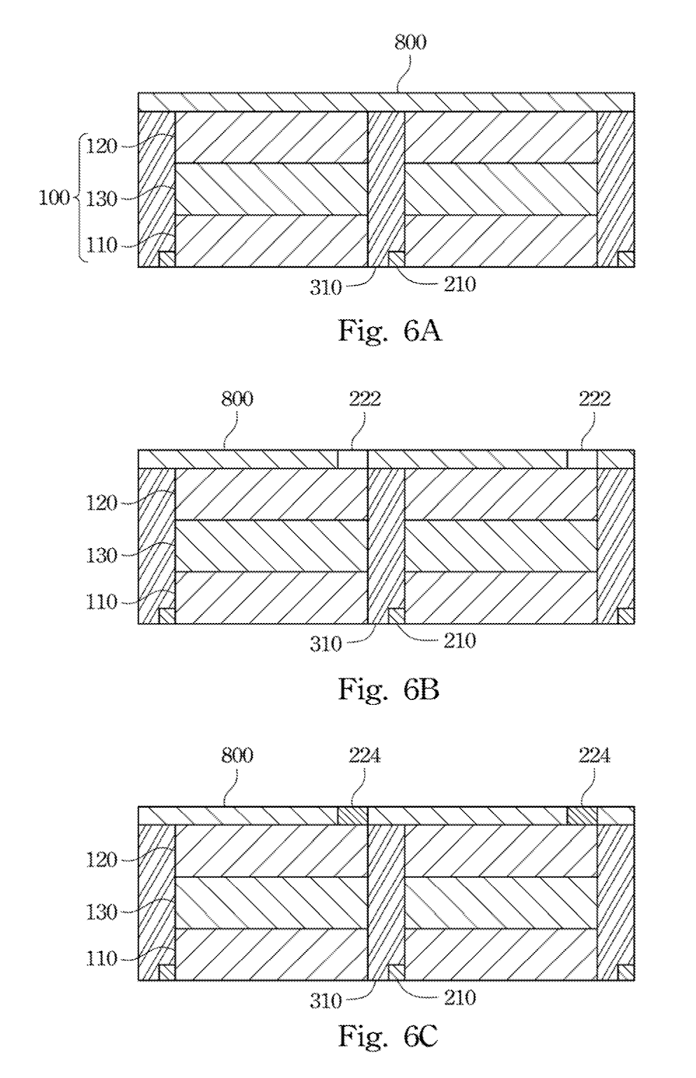

FIG. 36 is a cross-sectional view of the LED component in accordance with yet another embodiment of the present invention. In this embodiment, the thickness of the second electrode 200 is greater than the thickness of the passivation layer 330b.

As shown in FIGS. 1, 2, 3A and 3B, in some embodiments, the semiconductor epitaxial stack structure 100 includes a second semiconductor to layer 120, an illumination layer 130 and a first semiconductor layer 110. The first semiconductor layer 110 is disposed on the illumination layer 130, and the illumination layer 130 is disposed on the second semiconductor layer 120. The first electrode 210 is disposed on the lateral surface of the first semiconductor layer 110, and the second electrode 220 is disposed on the bottom surface of the second semiconductor layer 120.

Specifically, the first semiconductor layer 110, the illumination layer 130 and the second semiconductor layer 120 respectively include lateral surfaces on one side, and these lateral surfaces are connected to form the first lateral surface 102 of the semiconductor epitaxial stack structure 100. Similarly, the first semiconductor layer 110, the illumination layer 130 and the second semiconductor layer 120 respectively include lateral surfaces on another side, and these lateral surfaces are connected to form the second lateral surface 104 of the semiconductor epitaxial stack structure 100. The first electrode 210 is disposed on the first lateral surface 102 and is connected to the first semiconductor layer 110. The second electrode 220 is disposed on the bottom surface 106 and is connected to the second semiconductor layer 120. Therefore, the first electrode 210 and the second electrode 220 can respectively apply voltage on the first semiconductor layer 110 and the second semiconductor layer 120 to drive the electrons and the electronic holes to move and to combine in the illumination layer 130, thereby to emit light.

In some embodiments, the first semiconductor layer 110 is an N-type semiconductor layer, and the first electrode 210 is an N electrode. The second semiconductor layer 120 is a P-type semiconductor layer, and the second electrode 220 is a P electrode. For example, the first semiconductor layer 110 is formed by a nitride semiconductor doped with N-type impurity, such as n-GaN, which is formed by doping the group 4A elements, such as Silicon, in the pure GaN. The second semiconductor layer 120 is a nitride semiconductor doped with P-type impurity, which is formed by doping the group 2A elements such as Magnesium, in the pure GaN.

In some embodiments, the first semiconductor layer 110 is a P-type semiconductor layer, and the first electrode 210 is a P electrode. The second semiconductor layer 120 is an N-type semiconductor layer, and the second electrode 220 is an N electrode. For example, the first semiconductor layer 110 is a nitride semiconductor doped with P-type impurity, which is formed by doping the group 2A elements, such as Magnesium, in the pure GaN. The second semiconductor layer 120 is formed by a nitride semiconductor doped with N-type impurity, such as n-GaN, which is formed by doping the group 4A elements, such as Silicon, in the pure GaN.

In some embodiments, the illumination layer 130 includes a plurality of quantum wells to assist the electrons and the electronic holes provided by the first semiconductor layer 110 and the second semiconductor layer 120 to combine therein.

FIG. 4A is a cross-sectional view of a LED package in accordance with one embodiment of the present invention. FIG. 4B is a partial side view of the LED package shown in FIG. 4A. FIG. 4C is a partial side view of the first lead frame 510 shown in FIG. 4A. As shown in FIGS. 4A to 4C, the LED package includes a LED component 400, a first lead frame 510, a second lead frame 520 and a package 600. The LED component 400 at least includes a semiconductor epitaxial stack structure 100, a first electrode 210 and a second electrode 220. Their space relations are described above, and therefore are not repeated herein. The first lead frame 510 is electrically connected to the first electrode 210 of the LED component 400. The second lead frame 520 is electrically connected to the second electrode 220 of the LED component 400. The package 600 contains the LED component 400, the first lead frame 510 and the second lead frame 520.

Because the first electrode 210 is disposed on the first lateral surface 102, the first lead frame 510 electrically connected to the first electrode 210 is close to the first lateral surface 102, and the first lead frame 510, therefore, does not block the light passing through the top surface 108 of the semiconductor epitaxial stack structure 100. Further, because the second electrode 220 is disposed under the bottom surface 106 of the semiconductor epitaxial stack structure 100, the second lead frame 520 electrically connected to the second electrode 220 is close to the bottom surface, and the second lead frame 520, therefore, does not block the light passing through the top surface 108 of the semiconductor epitaxial stack structure 100. Therefore, the top surface 108 is not shaded by any objects, so as to assist the light passing through.

In some embodiments, the height of the first lead frame 510 is not equal to the height of the second lead frame 520, and the first lead frame 510 is spaced apart from the second lead frame 520 by a distance. In other word the first lead frame 510 and the second lead frame 520 are not at the same horizontal level and also not physically contact to each other.

In some embodiments, the first lead frame 510 includes a first extension member 512. The first extension member 512 is extended from one side of the package 600 toward the first lateral surface 102 of the semiconductor epitaxial stack structure 100. The end of the first extension member 512 is electrically coupled to the first electrode 210. The LED package can further include a first conductive die-bonding glue 514 adhered between the first electrode 210 and the end of the first extension member 512. The end of the first extension member 512 includes a conductive glue containing notch 513, and the first conductive die-bonding glue 514 is filled in the conductive glue containing notch 513, so that the first electrode 210 can be adhered to and electrically connected to the first lead frame 510. Specifically, the conductive glue containing notch 513 is formed on the upper left corner of the first extension member 512. In this embodiment, the first conductive die-bonding glue 514 can be silver glue for achieving both conductive effect and adhering effect.

In some embodiments, the second lead frame 520 includes a second extension member 522. The second extension member 522 is extended from another side of the package 600 toward the second lateral surface 104 of the semiconductor epitaxial stack structure 100. The second extension member 522 is positioned under the semiconductor epitaxial stack structure 100 for supporting the second electrode 220.

The package 600 may include a first lateral wall 610 and a second lateral wall 620. Then first lateral wall 610 and the second lateral wall 620 are respectively formed on opposite sides of the package 600. The first extension member 512 is extended from the first lateral wall 610 to the first electrode 210 on the first lateral surface 102. The second extension member 522 is extended from the second lateral wall 620 toward the second lateral surface 104, and is further extended to the position under the second electrode 220 for supporting the second electrode 220.

In some embodiments, the LED package further includes a second conductive die-bonding glue 700. The second conductive die-bonding glue 700 is adhered between the second electrode 220 and the surface of the second lead frame 520. Specifically, the second electrode 220 is fixed on the second extension member 522 of the second lead frame 520 by the second conductive die-bonding glue 700. The second conductive die-bonding glue 700 can be silver glue for achieving both conductive effect and adhering effect.

FIGS. 5A-5I are cross-sectional views of the LED components during the manufacturing process in accordance with one embodiment of the present invention. The main steps of the manufacturing method are described below.

As shown in FIG. 5A, in the manufacturing method of this embodiment, a substrate 800 can be provided at first, and the semiconductor epitaxial stack structure 100 can be formed on the substrate 800. In this embodiment, the semiconductor epitaxial stack structure 100 includes a second semiconductor layer 120, an illumination layer 130 and a first semiconductor layer 110. The second semiconductor layer 120 is disposed on the substrate 800, and the illumination layer 130 is disposed on the second semiconductor layer 120, and the first semiconductor layer 110 is disposed on the illumination layer 130.

It is noted that “feature A is disposed on feature B” in this specification refers that the feature A is positioned above feature B directly or indirectly. In other words, the projection of feature A projected to the plane of feature B covers feature B. Therefore, feature A can not only directly be stacked on feature B, a feature C can also be put between feature A and feature B, as long as feature A is still positioned above feature B. For example, “the second semiconductor layer 120 is disposed on the substrate 800” not only includes the embodiment in which the second semiconductor layer 120 is directly stacked on the substrate 800, but also includes the embodiment in which some other elements are put between the second semiconductor 120 and the substrate 800.

As shown in FIG. 5B, in this embodiment, the first semiconductor layer 110, the illumination layer 130 and the second semiconductor layer 120 can be etched to form at least two grooves 312 for insulation layers on the substrate 800. For example, the manufacturer can etch the first semiconductor layer 110 toward the second semiconductor layer 120 by dry etching or wet etching, and can stop etching when the substrate 800 is exposed, so that the grooves 312 for insulation layers can be formed.

As shown in FIG. 5C, in this embodiment, at least one insulation material 314 can be deposited in the grooves 312 (See FIG. 5B) for insulation layers to form the first insulation layer 310 and the second insulation layer 320 (See FIG. 2). In some embodiments, the insulation material 314 can be SiO₂.

As shown in FIG. 5D, in this embodiment, the first insulation layer 310 can be etched to form a first electrode groove 212 on a lateral surface of the first semiconductor layer 110. For example, the manufacturer can etch the first insulation layer 310 downwards to form the first electrode groove 212. The first electrode groove 212 exposes the lateral surface of the first semiconductor layer 110.

As shown in FIG. 5E, in this embodiment, at least one first conductive material 214 is deposited in the first electrode groove 212 to form at least one first electrode 210 (See FIG. 2). For example, the first conductive material 214 can be filled in the first electrode groove 212 by evaporation to form the first electrode 210. In some embodiments, the first conductive material 214 may include, but is not limited to include, Indium Tin Oxide (ITO).

As shown in FIG. 5F, in this embodiment, the substrate 800 and the semiconductor epitaxial stack structure 100 can be inverted, and the substrate 800 can be removed to expose the bottom surface of the second semiconductor layer 120. For example, the substrate 800 can be separated from the second semiconductor layer 120 by the laser beam.

As shown in FIG. 5G, in this embodiment, a passivation layer 330a can be deposited on the bottom surface of the second semiconductor layer 120. For example, the insulation material can be coated on the second semiconductor layer 120 by evaporation to form the passivation layer 330a. In some embodiments, the passivation layer 330a can be formed by SiO₂.

As shown in FIG. 5H, in this embodiment, part of the passivation layer 330a can be etched to form at least one second electrode groove 222 on the second semiconductor layer 120. For example, the manufacturer can etch the passivation layer 330a downwards by dry etching or wet etching to expose part of the second semiconductor layer 120, and the formed recess can be used as the second electrode groove 222

As shown in FIG. 5I, in this embodiment, at least one second conductive material 224 can be deposited in the second electrode groove 222 to form the second electrode 220 (See FIG. 2) on the bottom surface of the second semiconductor layer 120. For example, the second conductive material 224 can be filled in the second electrode groove 222 by evaporation to form the second electrode. In some embodiments, the second conductive material 224 may include, but is not limited to include, metal or ITO. In some embodiments, the first conductive material 214 and the second conductive material 224 can be the same or different.

In the end, the structure in FIG. 5 can be cut to form several separated LED components as shown in FIG. 2.

FIGS. 6A to 6C are cross-sectional views of the LED components during the manufacturing process in accordance with another embodiment of the present invention. This embodiment is similar to which is shown in FIGS. 5A to 5I, and the main difference is the method for manufacturing the second electrode 220. The method for manufacturing the second electrode 220 in this embodiment is described below.

As shown in FIG. 6A, in this embodiment, the substrate 800 and the semiconductor epitaxial stack structure 100 can be inverted, but the substrate 800 is not removed.

As shown in FIG. 66, in this embodiment, part of the substrate 800 is directly etched to form at least one second electrode groove 222 on the substrate 800 to expose part of the bottom surface of the second semiconductor layer 120. For example, the manufacturer can etch the substrate 800 downwards by dry etching or wet etching to expose part of the second semiconductor layer 120, and the formed recess can be used as the second electrode groove 222.

In some embodiments, the manufacturer can alternatively thin the substrate 800 before etching it, so as to facilitate the etching process.

As shown in FIG. 6C, in this embodiment, at least one second conductive material 224 can be deposited in the second electrode groove 222 to form the second electrode 220 (See FIG. 3A) on the bottom surface of the second semiconductor layer 120. For example, the second conductive material 224 can be filled in the second electrode groove 222 by evaporation to form the second electrode 220. In some embodiments, the second conductive material 224 may include, but is not limited to include, metal or ITO. In some embodiments, the first conductive material 214 and the second conductive material 224 can be the same or different.

In the end, the structure in FIG. 6C can be cut to form several separated LED components as shown in FIG. 3A.

Further, when the manufacturer desires to form the structure as shown in FIG. 3B, in which the second electrode 220 is thicker than the passivation layer 330b, the second electrode 220 can be deposited thicker by evaporation during the step shown in FIG. 6C.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A light emitting diode component, comprising:
a semiconductor epitaxial stack structure having a bottom surface, a top surface opposite to the bottom surface, a first lateral surface, and a second lateral surface opposite to the first lateral surface;
a first electrode disposed on the first lateral surface of the semiconductor epitaxial stack structure; and
a second electrode disposed on the bottom surface of the semiconductor epitaxial stack structure.

2. The light emitting diode component of claim 1, further comprising a first insulation layer covering an area in the first lateral surface not occupied by the first electrode.

3. The light emitting diode component of claim 2, further comprising a second insulation layer covering the second lateral surface.

4. The light emitting diode component of claim 3, further comprising a passivation layer covering an area in the bottom surface not occupied by the second electrode, and covering the opposite lateral walls of the second electrode, wherein the passivation layer is adjacent to the first insulation layer and the second insulation layer.

5. The light emitting diode component of claim 4, wherein the passivation layer is an insulation layer or a semiconductor substrate.

6. The light emitting diode component of 5, wherein the semiconductor substrate is a sapphire substrate or a silicon substrate.

7. The light emitting diode component of 6, wherein the semiconductor epitaxial stack structure sequentially comprises a second semiconductor layer, an illumination layer and a first semiconductor layer, wherein the illumination layer is disposed on the second semiconductor layer, and the first semiconductor layer is disposed on the illumination layer; and the first electrode is disposed on the lateral surface of the first semiconductor layer, and the second electrode is disposed on the bottom surface of the second semiconductor layer.

8. The light emitting diode component of claim 7, wherein the first semiconductor layer is an N-type semiconductor layer, and the first electrode is an N electrode; and the second semiconductor layer is a P-type semiconductor layer, and the second electrode is a P electrode; or the first semiconductor layer is a P-type semiconductor layer, and the first electrode is a P electrode, and the second semiconductor layer is an N-type semiconductor layer, and the second electrode is an N electrode.

9. The light emitting diode component of claim 8, wherein the N-type semiconductor layer is formed by a nitride semiconductor doped with N-type impurity, and the P-type semiconductor is a nitride semiconductor doped with P-type impurity.

10. A light emitting diode package, comprising:
a light emitting diode component comprising:
a semiconductor epitaxial stack structure having a bottom surface, a top surface opposite to the bottom surface, a first lateral surface, and a second lateral surface opposite to the first lateral surface;
a first electrode disposed on the first lateral surface of the semiconductor epitaxial stack structure; and
a second electrode disposed on the bottom surface of the semiconductor epitaxial stack structure;
a first lead frame electrically connected to the first electrode of the light emitting diode component;
a second lead frame electrically connected to the second electrode of the light emitting diode component; and
a package containing the light emitting diode component, the first lead frame and the second lead frame.

11. The light emitting diode package of claim 10, wherein the height of the first lead frame is not equal to the height of the second lead frame, and the first lead frame is spaced apart from the second lead frame by a distance.

12. The light emitting diode package of claim 11, wherein the first lead frame comprises a first extension member extended from one side of the package toward the first lateral surface of the semiconductor epitaxial stack structure, and the end of the first extension member is electrically coupled to the first electrode.

13. The light emitting diode package of claim 12, further comprising a first conductive die-bonding glue adhered between the first electrode and the end of the first extension member;
wherein the end of the first extension member comprises a conductive glue containing notch, and the first conductive die-bonding glue is filled in the conductive glue containing notch.

14. The light emitting diode package of claim 11, wherein the second lead frame comprises a second extension member extended from another side of the package toward the second lateral surface of the semiconductor epitaxial stack structure, and the second extension member is positioned under the semiconductor epitaxial stack structure for supporting the second electrode.

15. The light emitting diode package of claim 14, further comprising a second conductive die-bonding glue adhered between the second electrode and the surface of the second lead frame.

16. The light emitting diode package of claim 10, further comprising a first insulation layer covering an area in the first lateral surface not occupied by the first electrode, and a second insulation layer covering the second lateral surface.

17. The light emitting diode package of claim 16, further comprising a passivation layer covering an area in the bottom surface not occupied by the second electrode, and covering the opposite lateral walls of the second electrode, wherein the passivation layer is adjacent to the first insulation layer and the second insulation layer.

18. A method for manufacturing the light emitting diode component, comprising the steps of:
providing a substrate;
forming a semiconductor epitaxial stack structure on the substrate, wherein the semiconductor epitaxial stack structure sequentially comprises a second semiconductor layer disposed on the substrate, an illumination layer on the second semiconductor layer and a first semiconductor layer on the illumination layer;
etching the first semiconductor layer, the illumination layer and the second semiconductor layer to form at least two grooves for insulation layers on the substrate;
depositing at least one insulation material in the grooves for insulation layers to form at least one first insulation layer and a second insulation layer;
etching the first insulation layer to form a first electrode groove on a lateral surface of the first semiconductor layer;
depositing at least one first conductive material in the first electrode groove to form at least one first electrode; and
forming at least one second electrode on the bottom surface of the second semiconductor layer.

19. The method for manufacturing the light emitting diode component of claim 18, wherein the step of forming the second electrode on the bottom surface of the second semiconductor layer comprises:
inverting the substrate and the semiconductor epitaxial stack structure;
removing the substrate to expose the bottom surface of the second semiconductor layer;
depositing a passivation layer on the bottom surface of the second semiconductor layer;
etching part of the passivation layer to form at least one second electrode groove on the second semiconductor layer; and
depositing at least one second conductive material in the second electrode groove to form the second electrode on the bottom surface of the second semiconductor layer.

20. The method for manufacturing the light emitting diode component of claim 18, wherein the step of forming the second electrode on the bottom surface of the second semiconductor layer comprises:
inverting the substrate and the semiconductor epitaxial stack structure;
etching part of the substrate to form at least one second electrode groove on the substrate to expose part of the bottom surface of the second semiconductor layer; and
depositing at least one second conductive material in the second electrode groove to form the second electrode on the bottom surface of the second semiconductor layer.
